(19) United States
(12) Patent Application Publication
(10) Pub. No.: US 2008/0188049 A1
(43) Pub. Date: Aug. 7, 2008

(54) Methods of Manufacturing Non-Volatile Memory Devices Including Charge-Trapping Layers

(75) Inventors: Woo Gwan Shim, Gyeonggi-do (KR); Mong-Sup Lee, Seoul (KR); Ji-Hoon Cha, Seoul (KR); Chang-Ki Hong, Gyeonggi-do (KR); Kun-Tack Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/022,735

(22) Filed: Jan. 30, 2008

(30) Foreign Application Priority Data
Feb. 1, 2007 (KR) 2007-10427

(51) Int. Cl. H01L 21/336

(52) U.S. Cl. 438/287; 257/E21.423

(57) ABSTRACT

Methods of manufacturing non-volatile memory devices are provided including sequentially forming a tunnel insulating layer, a charge-trapping layer, a blocking layer and a conductive layer on a substrate having a channel region. The conductive layer is patterned to form a word line structure, and the blocking layer and the charge-trapping layer are etched using an aqueous acid solution as an etching solution to form a blocking layer pattern and a charge-trapping layer pattern.

### CROSS-REFERENCE TO RELATED APPLICATIONS

This application claims priority under 35 USC §119 to Korean Patent Application No. 2007-10427, filed on Feb. 1, 2007 in the Korean Intellectual Property Office (KIPO), the contents of which are incorporated herein by reference in their entirety.

### FIELD OF THE INVENTION

The present invention relates to semiconductor devices and, more In particular, to methods of manufacturing non-volatile memory devices.

### BACKGROUND OF THE INVENTION

Semiconductor memory devices, in general, are classified as either volatile or non-volatile semiconductor memory devices. Volatile semiconductor memory devices, such as dynamic random access memory (DRAM) devices and static random access memory (SRAM) devices have relatively high input/output (I/O) speeds. However, the volatile semiconductor memory devices lose data stored therein when power is shut off. On the other hand, although non-volatile semiconductor memory devices, such as electrically erasable programmable read-only memory (EEPROM) devices and/or flash memory devices, have relatively slow I/O speeds, non-volatile semiconductor memory devices are able to maintain data stored therein even when power is shut off.

In EEPROM devices, data is electrically stored, i.e., programmed or erased through a Fowler-Nordheim (F-N) tunneling mechanism and/or a channel hot electron injection mechanism. The flash memory device is classified as either a floating gate type or a charge trap type, such as silicon-oxide-nitride-oxide semiconductor (SONOS) type devices or metal-oxide-nitride-oxide semiconductor (MONOS) type devices.

The charge trap type non-volatile memory device includes a tunnel insulating layer formed on a channel region of a semiconductor substrate, a charge-trapping layer for trapping electrons from the channel region, a dielectric layer formed on the charge-trapping layer, a gate electrode formed on the dielectric layer, spacers formed on sidewalls of the gate electrode and source/drain regions formed at surface portions of the semiconductor substrate adjacent to the channel region.

When thermal stress is applied to the charge trap type non-volatile memory device, electrons trapped in the charge-trapping layer may be laterally diffused, thereby deteriorating high-temperature stress (HTS) characteristics of the non-volatile memory device. For example, when the non-volatile memory device is maintained at a temperature of about 200° C. for about 2 hours, the threshold voltage of the non-volatile memory device may be remarkably reduced. In particular, when programming and erasing operations of the non-volatile memory device are repeatedly performed about 1,000 to about 1,200 times, and the non-volatile memory device is then maintained at a temperature of about 200° C. for about 2 hours, the threshold voltage of the non-volatile memory device may be increasingly reduced.

### SUMMARY OF THE INVENTION

Some embodiments of the present invention provide methods of manufacturing a non-volatile memory device, the method including sequentially forming a tunnel insulating layer, a charge-trapping layer, a blocking layer and a conductive layer on a semiconductor substrate having a channel region. The conductive layer is patterned to form a word line structure, and the blocking layer and the charge-trapping layer is etched using an acid aqueous solution as an etching solution to form a blocking layer pattern and a charge-trapping layer pattern over the channel region. Impurity regions are formed at portions of the substrate on both sides of the channel region.

In further embodiments of the present invention, the blocking layer may include aluminum oxide, and the charge-trapping layer may include silicon nitride.

In still further embodiments of the present invention, the blocking layer and the charge-trapping layer may be etched using an aqueous phosphoric acid solution.

In some embodiments of the present invention, a temperature of the aqueous phosphoric acid solution may be controlled in a range of from about 100° C. to about 200° C.

In further embodiments of the present invention, the aqueous phosphoric acid solution may include from about 5.0 to about 50 percent by weight of water.

In still further embodiments of the present invention, the blocking layer and the charge-trapping layer may be etched in an airtight container. For example, the substrate may be placed in a container receiving the aqueous phosphoric acid solution to immerse the substrate in the aqueous phosphoric acid solution, and the container may be closed such that it is air tight. Then, the airtight container may be heated to raise a temperature of the aqueous phosphoric acid solution so that an etching rate may be increased.

In some embodiments of the present invention, the container may be cooled to lower the temperature of the aqueous phosphoric acid solution after forming the blocking layer pattern and the charge-trapping layer pattern. In certain embodiments of the present invention, an inert gas may be supplied into the container.

In further embodiments of the present invention, the blocking layer and the charge-trapping layer may be etched using different aqueous acid solutions. For example, the blocking layer may be etched using an aqueous phosphoric acid solution, and the charge-trapping layer pattern may be etched using an aqueous sulfuric acid solution. In such a case, a temperature of the aqueous phosphoric acid solution may be controlled in a range of from about 100° C. to about 200° C., and the aqueous solution of phosphoric acid may include from about 5.0 to about 50 percent by weight of water.

In still further embodiments of the present invention, the blocking layer may be etched in an airtight container. For example, the substrate may be placed in a container receiving the aqueous phosphoric acid solution to immerse the substrate in the aqueous phosphoric acid solution, and the container may be air tight. Then, the airtight container may be heated to raise a temperature of the aqueous phosphoric acid solution so that an etching rate may be increased.

In some embodiments of the present invention, the container may be cooled to lower the temperature of the aqueous phosphoric acid solution after forming the blocking layer pattern. In certain embodiments, an inert gas may be supplied into the container.

In further embodiments of the present invention, a temperature of the aqueous sulfuric acid solution may be controlled in a range of from about 100° C. to about 200° C.

In still further embodiments of the present invention, the aqueous sulfuric acid solution may include from about 5.0 to about 50 percent by weight of water.

In some embodiments of the present invention, the charge-trapping layer may be etched in an airtight container. For example, the substrate may be placed in a container receiving the aqueous sulfuric acid solution to immerse the substrate in the aqueous sulfuric acid solution, and the container may be air. Then, the airtight container may be heated to raise a temperature of the aqueous sulfuric acid solution so that an etching rate may be increased.

In further embodiments of the present invention, the container may be cooled to lower the temperature of the aqueous sulfuric acid solution after forming the charge-trapping layer pattern. In certain embodiments, an inert gas may be supplied into the container.

In still further embodiments of the present invention, the charge-trapping layer pattern may be formed using an aqueous oxalic acid solution.

In some embodiments of the present invention, spacers may be formed on side surfaces of the word line structure, and each of the spacers may include silicon oxide and silicon nitride.

In further embodiments of the present invention, a silicon oxide layer may be formed on the word line structure and the blocking layer, and a silicon nitride layer may be formed on the silicon oxide layer. The silicon nitride layer and the silicon oxide layer may be anisotropically etched to form the spacers.

### BRIEF DESCRIPTION OF THE DRAWINGS

FIGS. 1 through 4 and 8 are cross-sections and an electron microscope picture illustrating methods of manufacturing non-volatile memory devices according to some embodiments of the present invention.

FIG. 5 is a graph illustrating an etching rate of aluminum oxide in an etching process using an aqueous phosphoric acid solution.

FIG. 6 is a graph illustrating etching rates of silicon nitride, aluminum oxide and tantalum nitride in an etching process using an aqueous phosphoric acid solution.

FIG. 7 is a graph illustrating an etching rate of silicon nitride in an etching process using an aqueous sulfuric acid solution.

FIGS. 9 through 12 and 14 are cross sections and an electron microscope picture illustrating methods of manufacturing non-volatile memory devices according to some embodiments of the present invention.

FIG. 13 is an electron microscope picture illustrating a blocking layer pattern and a charge-trapping layer pattern formed by an anisotropic dry etching process.

### DESCRIPTION OF THE EMBODIMENTS

Embodiments of the invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

Example embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

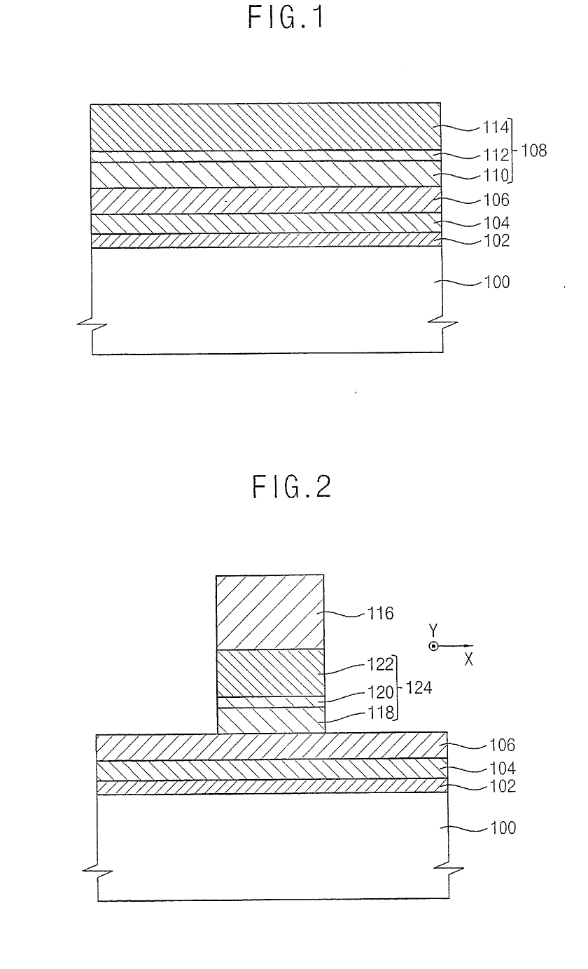

As discussed herein with respect to FIGS. 1 through 14, according to some embodiments of the present invention, a charge-trapping layer may be partially etched to form a charge-trapping layer pattern until a tunnel-insulating layer is at least exposed. Thus, the lateral charge diffusion in a non-volatile memory may be reduced or possibly prevented. As a result, high-temperature stress (HTS) characteristics and data reliability of the non-volatile memory device may be improved.

FIGS. 1 to 4 and 8 are cross sections and an electron microscope picture illustrating methods of manufacturing non-volatile memory devices according to some embodiments of the present invention. As illustrated in FIG. 1, an isolation layer (not shown) may be formed to define an active region in a surface portion of a semiconductor substrate 100 such as a silicon wafer. For example, the isolation layer may be formed in the surface portion of the semiconductor substrate 100 by a local oxidation of silicon (LOCOS) or a shallow trench isolation (STI) process.

A tunnel insulating layer 102, a charge-trapping layer 104, a blocking layer 106 and a conductive layer 108 may be sequentially formed on the semiconductor substrate 100. The tunnel-insulating layer 102 may include silicon oxide (SiO₂), and may be formed to a thickness of from about 20 Å to about 80 Å by a thermal oxidation process. For example, the tunnel-insulating layer 102 may be formed to a thickness of about 35 Å on the semiconductor substrate 100.

The charge-trapping layer 104 is formed to trap electrons from a channel region of the semiconductor substrate 100. The charge-trapping layer 104 may be formed to a thickness of from about 20 Å to about 100 Å on the tunnel-insulating layer 102 and may include silicon nitride (SiN). For example, the charge-trapping layer 104 may be formed to a thickness of about 70 Å on the tunnel-insulating layer 102 by a low-pressure chemical vapor deposition (LPCVD) process.

In some embodiments of the present invention, the charge-trapping layer 104 may include a high-k material having a dielectric constant k higher than that of silicon nitride. Examples of the high-k material may include metal oxide, metal oxynitride, metal silicon oxide, metal silicon oxynitride, and the like. These materials can be used alone or in a combination thereof. In particular, examples of a metal that may be used for the high-k material may include hafnium (Hf), zirconium (Zr), aluminum (Al), tantalum (Ta), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), and the like. These metals can be used alone or combination without departing from the scope of the present invention.

The blocking layer 106 may be formed to provide electrical insulation between the charge-trapping layer 104 and the conductive layer 108. The blocking layer 106 may include aluminum oxide (Al₂O₃) and may be formed by a chemical vapor deposition (CVD) process or an atomic layer deposition (ALD) process. For example, the blocking layer 106 may be formed to a thickness of about 100 Å to about 400 Å on the charge-trapping layer 104. In particular, the blocking layer 106 may be formed to a thickness of about 200 Å on the charge-trapping layer 104.

The conductive layer 108 may include a first metal nitride layer 110, a second metal nitride layer 112 and a metal layer 114. Examples of a metal that may be used for the first metal nitride layer 110 may include tantalum nitride, titanium nitride, hafnium nitride, and the like. These metal nitrides may be used alone or in a combination thereof. For example, the first metal nitride layer 110 may include tantalum nitride and may be formed to a thickness of about 200 Å on the blocking layer 106.

The second metal nitride layer 112 may serve as an adhesion layer and may include tungsten nitride. For example, the second metal nitride layer 1 12 may be formed to a thickness of about 50 Å on the first metal nitride layer 110. The metal layer 114 may include tungsten and may be formed to a thickness of about 300 Å on the second metal nitride layer 112. Alternatively, the metal layer 114 may include metal silicide. Examples of the metal silicide may include tungsten silicide, tantalum silicide, cobalt silicide, titanium silicide, and the like. These metal silicides may be used alone or in a combination thereof.

Referring to FIG. 2, a hard mask layer (not shown) may be formed on the conductive layer 108. The hard mask layer may include silicon oxide and may be formed to a thickness of about 500 Å to about 1,500 Å on the conductive layer 108. The hard mask layer may be patterned to form a hard mask 116 on the conductive layer 108. The hard mask 116 may be formed by an anisotropic etching process using a photoresist pattern. The photoresist pattern may be formed on the hard mask layer by a photolithography process and may be removed by an ashing process and/or a stripping process after forming the hard mask 116.

The conductive layer 108 may be patterned to form a word line structure 124 that includes a first metal nitride layer pattern 118, a second metal nitride layer pattern 120 and a metal layer pattern 122, on the blocking layer 106. The conductive layer 108 may be patterned by an anisotropic etching process using the hard mask 116 as an etching mask. Here, the first metal nitride layer pattern 118 may substantially serve as a gate electrode, and the metal layer pattern 122 may substantially serve as a word line.

As illustrated in FIG. 2, although one word line structure 124 is depicted, a plurality of word line structures may be arranged in an X-axis direction, and each of the word line structures may extend in a Y-axis direction without departing from the scope of the present invention.

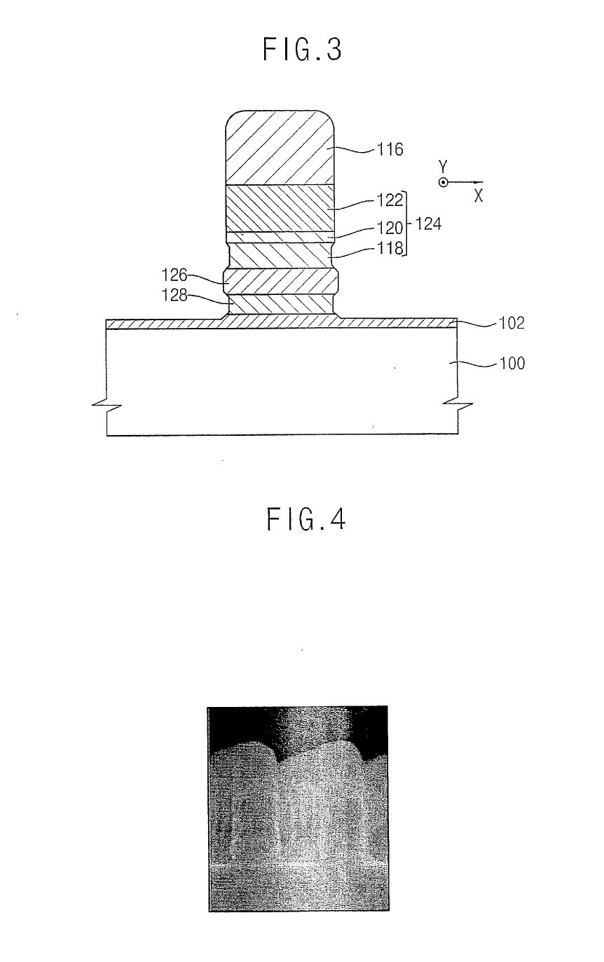

Referring now to FIGS. 3 and 4, the blocking layer 106 and the charge-trapping layer 104 may be etched to form a blocking layer pattern 126 and a charge-trapping layer pattern 128. The blocking layer 106 and the charge-trapping layer 104 may be patterned by a wet etching process using an acid aqueous solution as an etching solution. Examples of the acid aqueous solution may include an aqueous phosphoric acid solution including from about 5.0 to about 50 percent by weight of water. In particular, the aqueous phosphoric acid solution may include from about 5.0 to about 10 percent by weight of water. For example, the wet etching process may be performed using an aqueous phosphoric acid solution including about 8.0 percent by weight of water.

The wet etching process may be performed at a temperature of from about 100° C. to about 200° C. In particular, the wet etching process may be performed at a temperature of from about 150° C. to about 170° C., for example, a temperature of about 160° C. In some embodiments, the wet etching process may be performed in an airtight container. A pressure in the container may be controlled to not exceed about 2.0 atm with due regard to an explosion of the container.

For example, the aqueous phosphoric acid solution may be received in the container, and the semiconductor substrate 100 may be placed in the container so as to immerse the semiconductor substrate 100 in the aqueous phosphoric acid solution. Then, the container may be closed such that it is airtight. Here, an inert gas may be supplied in the container so that air in the container may be removed. The container may be heated to adjust a temperature of the aqueous phosphoric acid solution. The pressure in the container may be increased by heating the container, and thus an evaporation point of the aqueous phosphoric acid solution may be raised.

The wet etching process may be performed for a predetermined time. The container may be cooled to unload the semiconductor substrate 100 from the container after performing the wet etching process. The temperature of the aqueous phosphoric acid solution and the pressure in the container may be lowered. The semiconductor substrate 100 may be unloaded from the container after the temperature of the aqueous phosphoric acid solution is sufficiently lowered.

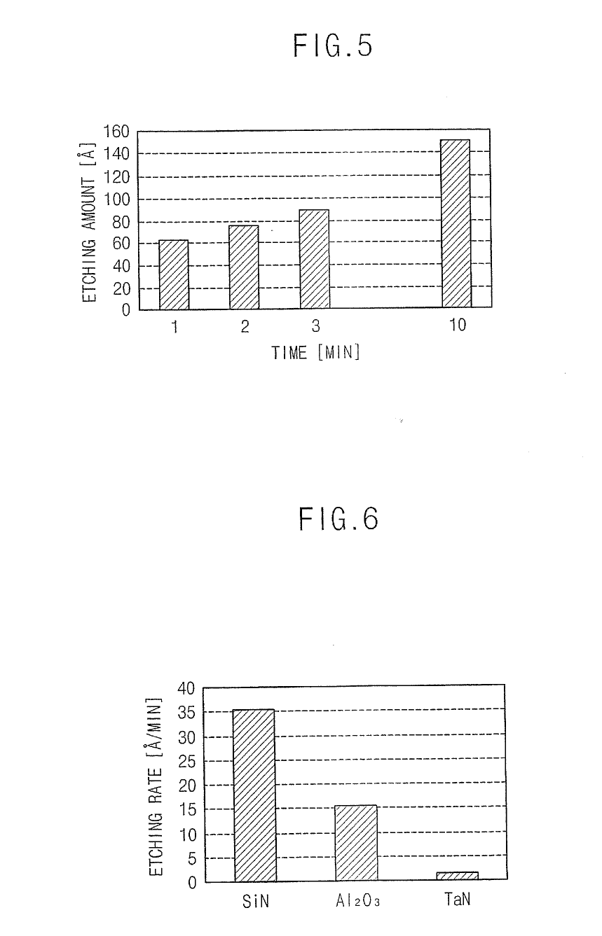

Referring now to FIGS. 5 and 6, a graph showing an etching rate of aluminum oxide in an etching process using an aqueous phosphoric acid solution, and a graph showing etching rates of silicon nitride, aluminum oxide and tantalum nitride in an etching process using an aqueous phosphoric acid solution will be discussed. Because an etching rate of aluminum oxide is lower than that of silicon nitride in a wet etching process using an aqueous phosphoric acid solution as shown in FIGS. 5 and 6, the charge-trapping layer pattern 128 may have a width narrower than that of the blocking layer pattern 126 as shown in FIG. 4. In particular, the charge-trapping layer pattern 128 may have substantially the same width as the first metal nitride layer pattern 118 serving as the gate electrode. Thus, deterioration of the HTS characteristics caused by lateral charge diffusion may be reduced or possibly prevented. It is because portions of the charge-trapping layer 104 to which electrons trapped in the charge-trapping layer pattern 128 may laterally move may be sufficiently removed by the wet etching process. Meanwhile, the first metal nitride layer pattern 118, i.e., a tantalum nitride layer pattern, may be partially removed while forming the blocking layer pattern 126 and the charge-trapping layer pattern 128.

Typically, when a blocking layer pattern and a charge-trapping layer pattern are formed by an anisotropic dry etching process, by-products may be generated by a reaction between chlorine in an etching gas and tungsten and/or tantalum nitride while performing the anisotropic dry etching process, and a surface profile of word line structures may be deteriorated by the by-products. Furthermore, portions of a charge-trapping layer between the word line structures may not be sufficiently removed and may remain on a tunnel insulating layer. The charge-trapping layer pattern formed by the anisotropic dry etching process may have a width wider than that of the blocking layer pattern. Thus, lateral charge diffusion in the charge-trapping layer pattern cannot be sufficiently reduced. However, portions of the charge-trapping layer 104 adjacent to the word line structure 124, i.e., portions of the charge-trapping layer 104 between the word line structures 124, may be sufficiently removed by the wet etching process, and thus the lateral charge diffusion may be sufficiently reduced or possibly prevented.

Some embodiments of the present invention, the blocking layer pattern 126 and the charge-trapping layer pattern 128 may be formed using different aqueous acid solutions from each other. For example, the blocking layer pattern 126 may be formed using an aqueous phosphoric acid solution, and the charge-trapping layer pattern 128 may be formed using an aqueous sulfuric acid solution.

In particular, a first wet etching process using the aqueous phosphoric acid solution may be performed to form the blocking layer pattern 126, and a second wet etching process using the aqueous sulfuric acid solution may then be performed to form the charge-trapping layer pattern 128.

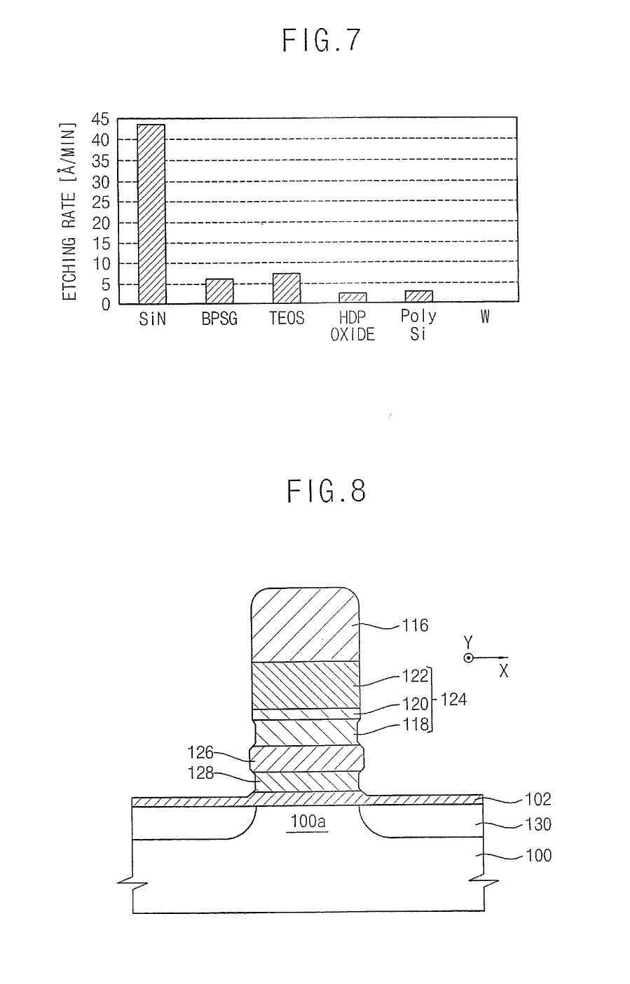

FIG. 7 is a graph showing an etching rate of silicon nitride in an etching process using an aqueous sulfuric acid solution. Further detailed descriptions for the first wet etching process will be omitted since these are similar to those of the wet etching process already described with reference to FIGS. 3 and 4.

The second wet etching process may be performed at a temperature of from about 100° C. to about 200° C. For example, the second wet etching process may be performed at a temperature of from about 110° C. and about 160° C. The aqueous sulfuric acid solution may include from about 5.0 to about 50 percent by weight of water. In particular, the aqueous sulfuric acid solution may include from about 5.0 to about 10 percent by weight of water, for example, about 8.0 percent by weight of water.

An etching rate of silicon nitride for an aqueous sulfuric acid solution having a temperature of about 120° C. is relatively high in comparison with those of silicon oxide, polysilicon, tungsten, and the like. As shown in FIG. 7, the etching rate of silicon nitride for an aqueous sulfuric acid solution is about 43 Å/min at a temperature of about 120° C.

The second wet etching process may be performed in substantially the same method as in the first wet etching process. In particular, the aqueous sulfuric acid solution may be received in a container, and the semiconductor substrate 100 may be placed in the container so that the semiconductor substrate 100 is immersed in the aqueous sulfuric acid solution. The container may be closed such that it is air tight and may be heated to adjust a temperature of the aqueous sulfuric acid solution. Here, it is desired that a pressure in the container is controlled to not exceed about 2 atm with due regard to an explosion of the container. The second wet etching process may be performed for a predetermined time. The container may be cooled to lower the temperature of the aqueous sulfuric acid solution and the pressure in the container, and the semiconductor substrate 100 may then be unloaded from the container.

In some embodiments of the present invention, the charge-trapping layer pattern 128 may be formed using an aqueous oxalic acid solution.

Referring now to FIG. 8, the charge-trapping layer pattern 128, the blocking layer pattern 126 and the word line structure 124 may be disposed on a channel region 100a of the semiconductor substrate 100. After forming the charge-trapping layer pattern 128 and the blocking layer pattern 126, impurity regions 130 may be formed at surface portions of the semiconductor substrate 100 on both sides of the channel region 100a. The impurity regions 130 may serve as source/drain regions and may be formed by an ion implantation process and a heat treatment.

Although not shown in the figures, an insulating interlayer may be formed to fill up spaces between the word line structures 124 so that memory cells of the non-volatile memory device may be electrically isolated from one another.

In some embodiments of the present invention, when the charge-trapping layer 104 may include the high-k material, the charge-trapping layer pattern 128 may be formed using an aqueous hydrofluoric acid (diluted hydrofluoric acid) solution.

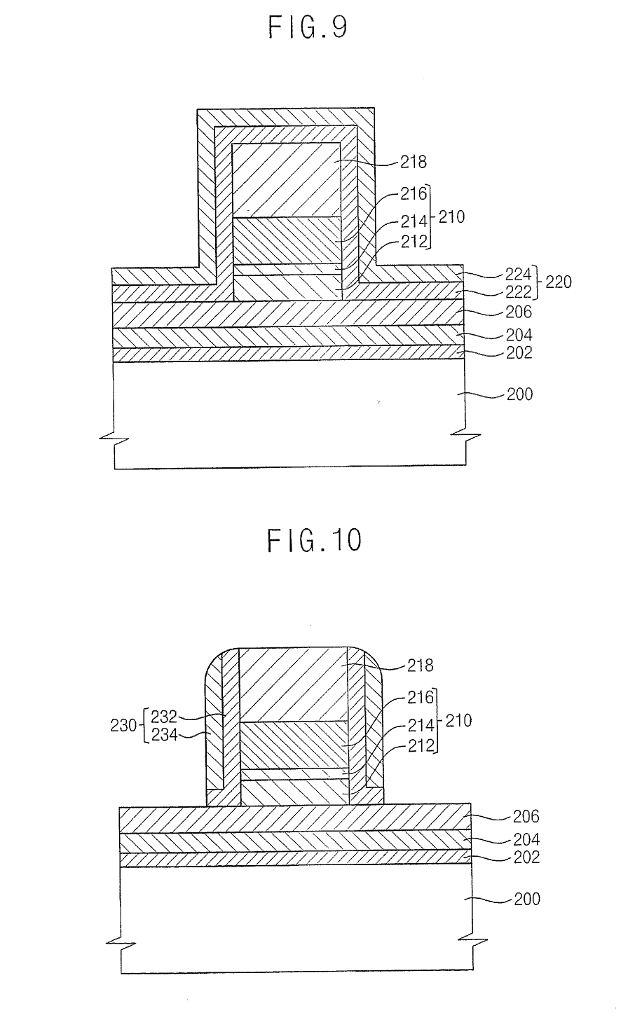

FIGS. 9 to 12 and 14 are cross sections and an electron microscope picture illustrating methods of manufacturing non-volatile memory devices according to some embodiments of the present invention. Referring first to FIG. 9, a tunnel insulating layer 202, a charge-trapping layer 204, a blocking layer 206 and a word line structure 210 may be formed on a semiconductor substrate 200 such as a silicon wafer. The word line structure 210 may include a first metal nitride layer pattern 212, a second metal nitride layer pattern 214 and a metal layer pattern 216. A hard mask 218 may be disposed on the word line structure 210. Further detailed descriptions for a method of forming the tunnel insulating layer 202, the charge-trapping layer 204, the blocking layer 206 and the word line structure 210 will be omitted since these elements are similar to those already described with reference to FIGS. 1 and 2.

After forming the word line structure 210, a spacer layer 220 may be formed on the hard mask 218, the word line structure 210 and the blocking layer 206. The spacer layer 220 may include silicon oxide and silicon nitride. In particular, a silicon oxide layer 222 may be formed on the hard mask 218, the word line structure 210 and the blocking layer 206, and a silicon nitride layer 224 may then be formed on the silicon oxide layer 222. The silicon oxide layer 222 and the silicon nitride layer 224 may be respectively formed by a CVD process. In accordance with another example embodiment of the present invention, the silicon nitride layer 224 may be formed in an in-situ manner after forming the silicon oxide layer 222. In particular, a middle temperature oxide (MTO) layer may be used as the silicon oxide layer 222.

Referring now to FIG. 10, the spacer layer 220 may be anisotropically etched to form spacers 230 on side surfaces of the word line structure 210. Each of the spacers 230 may include a silicon oxide spacer 232 and a silicon nitride spacer 234.

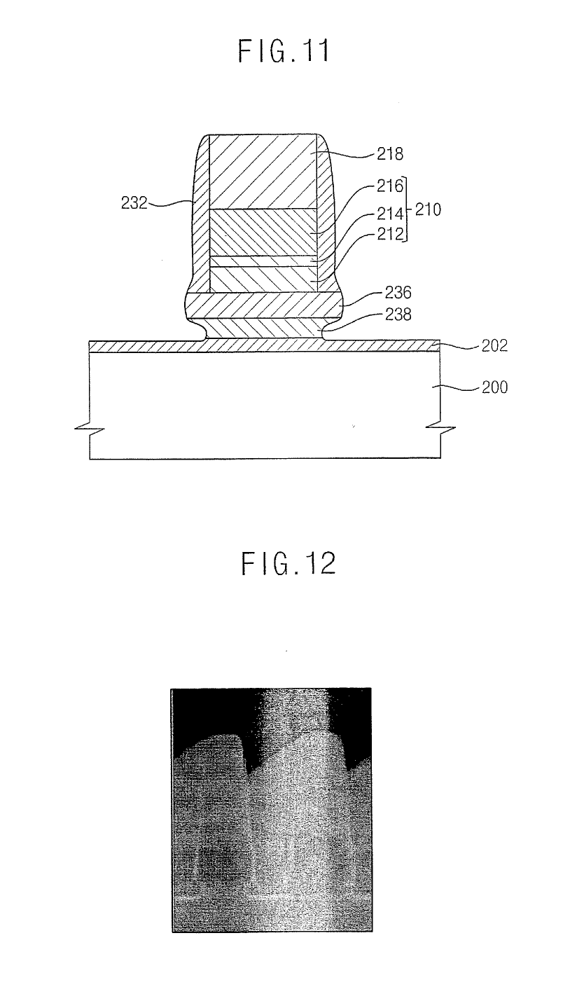

Referring now to FIGS. 11 and 12, the blocking layer 206 and the charge-trapping layer 204 may be etched to form a blocking layer pattern 236 and a charge-trapping layer pattern 238. The blocking layer pattern 236 and the charge-trapping layer pattern 238 may be formed by a wet etching process using an aqueous acid solution. An aqueous phosphoric acid solution may be used as the aqueous acid solution and may include from about 5.0 to about 50 percent by weight of water. In particular, the aqueous phosphoric acid solution may include from about 5.0 to about 10 percent by weight of water. For example, the wet etching process may be performed using an aqueous phosphoric acid solution including about 8.0 percent by weight of water.

The wet etching process may be performed at a temperature of from about 100° C. to about 200° C. In particular, the wet etching process may be performed at a temperature of from about 150° C. to about 170° C., for example, about 160° C.

Meanwhile, while performing the wet etching process using the aqueous phosphoric acid solution, the silicon nitride spacer 234 may be removed, and the silicon oxide spacer 232 may be partially removed.

The wet etching process using the aqueous phosphoric acid solution may be performed in an airtight container. Further detailed descriptions for the wet etching process will be omitted since these are similar to those already described with reference to FIGS. 3 and 4.

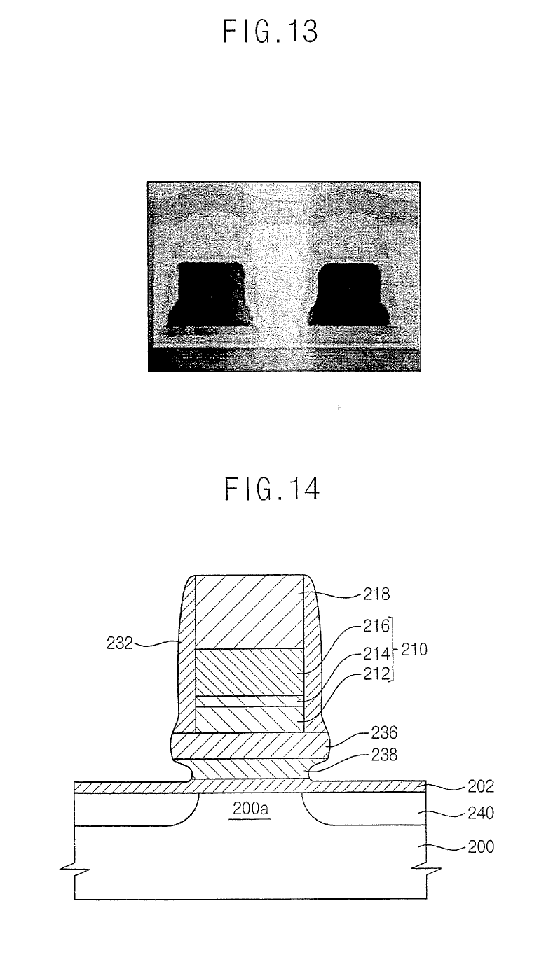

FIG. 13 is an electron microscope picture showing a blocking layer pattern and a charge-trapping layer pattern formed by an anisotropic dry etching process. Referring to FIG. 13, in a conventional method, when a block layer pattern and a charge-trapping layer pattern are formed by an anisotropic dry etching process, portions of a charge-trapping layer between word line structures may not be sufficiently removed and may remain on a tunnel insulating layer. The charge-trapping pattern formed by the anisotropic dry etching process may have a width wider than that of the blocking layer pattern. Thus, lateral charge diffusion in the charge-trapping layer pattern cannot be sufficiently reduced or possibly prevented.

However, portions of the charge-trapping layer 204 between the word line structures 210 may be sufficiently removed by the wet etching process, and further the charge-trapping layer pattern 238 may have a width narrower than that of the blocking layer pattern 236 as shown in FIG. 12. In particular, the charge-trapping layer pattern 238 may have substantially the same width as the word line structure 210. Thus, lateral charge diffusion in the charge-trapping layer pattern 238 may be sufficiently reduced or possibly prevented.

In some embodiments of the present invention, the blocking layer pattern 236 and the charge-trapping layer pattern 238 may be formed using different aqueous acid solution from each other. For example, the blocking layer pattern 236 may be formed using an aqueous phosphoric acid solution, and the charge-trapping layer pattern 238 may be formed using an aqueous sulfuric acid solution.

In particular, a first wet etching process using the aqueous phosphoric acid solution may be performed to form the blocking layer pattern 236, and a second wet etching process using the aqueous sulfuric acid solution may then be performed to form the charge-trapping layer pattern 238.

Further detailed descriptions for the first wet etching process will be omitted since these are similar to those of the wet etching process already described with reference to FIGS. 3 and 4.

The second wet etching process may be performed at a temperature of from about 100° C. to about 200° C. For example, the second wet etching process may be performed at a temperature of from about 110° C. and about 160° C. The aqueous sulfuric acid solution may include from about 5.0 to about 50 percent by weight of water. In particular, the aqueous sulfuric acid solution may include from about 5.0 to about 10 percent by weight of water, for example, about 8.0 percent by weight of water. Further detailed descriptions for the second wet etching process will be omitted since these are similar to those already described with reference to FIG. 7.

In some embodiments of present invention, the charge-trapping layer pattern 238 may be formed using an aqueous solution of oxalic acid.

Referring now to FIG. 14, the charge-trapping layer pattern 238, the blocking layer pattern 236, the word line structure 210 and the silicon oxide spacers 232 may be disposed on a channel region 200a of the semiconductor substrate 200.

After forming the charge-trapping layer pattern 238 and the blocking layer pattern 236, impurity regions 240 may be formed at surface portions of the semiconductor substrate 200 on both sides of the channel region 200a. The impurity regions 240 may serve as source/drain regions and may be formed by an ion implantation process and a heat treatment.

Although not shown in the figures, an insulating interlayer may be formed to fill up spaces between the word line structures 210 so that memory cells of the non-volatile memory device may be electrically isolated from one another.

In some embodiments of the present invention, when the charge-trapping layer 204 may include a high-k material, the charge-trapping layer pattern 238 may be formed using an aqueous hydrofluoric acid (diluted hydrofluoric acid) solution.

As discussed above, according to some embodiments of the present invention, a blocking layer pattern and a charge-trapping layer pattern may be formed using an aqueous acid solution. Thus, a width of the charge-trapping layer pattern may be reduced, and portions of a charge-trapping layer between word line structures may be sufficiently removed. As a result, lateral charge diffusion in the charge-trapping layer pattern may be sufficiently reduced or possibly prevented, and further HTS characteristics and data reliability of a non-volatile memory device including the charge-trapping layer pattern may be improved.

Although the example embodiments of the present invention have been described, it is understood that the present invention should not be limited to these example embodiments but various changes and modifications can be made by those skilled in the art within the spirit and scope of the present invention as hereinafter claimed.

That which is claimed is:

1. A method of manufacturing a non-volatile memory device, the method comprising:
forming a tunnel insulating layer, a charge-trapping layer, a blocking layer and a conductive layer on a substrate having a channel region;
patterning the conductive layer to form a word line structure;
etching the blocking layer and the charge-trapping layer using an aqueous acid solution as an etching solution to form a blocking layer pattern and a charge-trapping layer pattern over the channel region; and
forming impurity regions at surface portions of the substrate on both sides of the channel region.

2. The method of claim 1, wherein the blocking layer comprises aluminum oxide.

3. The method of claim 1, wherein the charge-trapping layer comprises silicon nitride.

4. The method of claim 1, wherein the blocking layer and the charge-trapping layer are etched using an aqueous phosphoric acid solution.

5. The method of claim 4, wherein a temperature of the aqueous phosphoric acid solution is controlled in a range of from about 100° C. to about 200° C.

6. The method of claim 4, wherein the aqueous phosphoric acid solution comprises from about 5.0 to about 50 percent by weight of water.

7. The method of claim 4, wherein etching the blocking layer and the charge-trapping layer comprises:
placing the substrate in a container receiving the aqueous phosphoric acid solution to immerse the substrate in the aqueous phosphoric acid solution;
closing the container such that the container is air tight; and
heating the airtight container to raise a temperature of the aqueous phosphoric acid solution.

8. The method of claim 7, wherein forming the blocking layer pattern and the charge-trapping layer pattern is followed by cooling the container to lower the temperature of the aqueous phosphoric acid solution.

9. The method of claim 7, wherein an inert gas is supplied into the container.

10. The method of claim 1, wherein etching the blocking layer and the charge-trapping layer comprises:
etching the blocking layer using an aqueous phosphoric acid solution to form the blocking layer pattern; and
etching the charge-trapping layer pattern using an aqueous sulfuric acid solution to form the charge-trapping layer pattern.

11. The method of claim 10, wherein a temperature of the aqueous phosphoric acid solution is controlled in a range of from about 100° C. to about 200° C.

12. The method of claim 10, wherein the aqueous phosphoric acid solution comprises from about 5.0 to about 50 percent by weight of water.

13. The method of claim 10, wherein etching the blocking layer comprises:
placing the substrate in a container receiving the aqueous phosphoric acid solution to immerse the substrate in the aqueous phosphoric acid solution;
closing the container such that the container is airtight; and
heating the airtight container to raise a temperature of the aqueous phosphoric acid solution.

14. The method of claim 13, further comprising cooling the container to lower the temperature of the aqueous phosphoric acid solution after forming the blocking layer pattern.

15. The method of claim 13, wherein an inert gas is supplied into the container.

16. The method of claim 10, wherein a temperature of the aqueous sulfuric acid solution is controlled in a range of from about 100° C. to about 200° C.

17. The method of claim 10, wherein the aqueous sulfuric acid solution comprises from about 5.0 to about 50 percent by weight of water.

18. The method of claim 10, wherein etching the charge-trapping layer comprises:
placing the substrate in a container receiving the aqueous sulfuric acid solution to immerse the substrate in the aqueous sulfuric acid solution;
closing the container such that the container is airtight; and
heating the airtight container to raise a temperature of the aqueous sulfuric acid solution.

19. The method of claim 18, further comprising cooling the container to lower the temperature of the aqueous sulfuric acid solution after forming the charge-trapping layer pattern.

20. The method of claim 18, wherein an inert gas is supplied into the container.

21. The method of claim 1, wherein the charge-trapping layer pattern is formed using an aqueous oxalic acid solution.

22. The method of claim 1, further comprising forming spacers on side surfaces of the word line structure.

23. The method of claim 22, wherein each of the spacers comprises silicon oxide and silicon nitride.

24. The method of claim 23, wherein forming the spacers comprises:
forming a silicon oxide layer on the word line structure and the blocking layer;
forming a silicon nitride layer on the silicon oxide layer; and
anisotropically etching the silicon nitride layer and the silicon oxide layer to form the spacers.
